(19) United States
(12) Patent Application Publication
(10) Pub. No.: US 2007/0250755 A1
(43) Pub. Date: Oct. 25, 2007

(54) Dormant error checker

(76) Inventors: Wayne Burleson, Shutesbury, MA (US); Mondira Pant, Westborough, MA (US); Shubhendu S. Mukherjee, Framingham, MA (US)

Correspondence Address: INTEL CORPORATION;c/o INTELLEVATE, LLC, P.O. BOX 52050, MINNEAPOLIS, MN, 55402, US

(21) Appl. No.: 11/393,178

(22) Filed: Mar. 29, 2006

(51) Int. Cl. G11C 29/00

(52) U.S. Cl. 714/763

(57) ABSTRACT

In accordance with some embodiments, an error checking scheme to check for an error in a memory unit during a dormant state is provided herein.

### BACKGROUND

Embodiments discussed herein relate generally to integrated circuits and in particular to error checking circuits.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of an error checking circuit in accordance with some embodiments.

FIG. 2 is a schematic diagram of a parity checking circuit in accordance with some embodiments.

FIG. 3 is a schematic diagram of a parity checking circuit suitable for implementing the parity circuit of FIG. 1 in accordance with some embodiments.

FIG. 4 is a block diagram of a computer system having a microprocessor with at least one error checking circuit in accordance with some embodiments.

### DETAILED DESCRIPTION

Typical error checking circuits have a limit on how many errors in a unit of memory (e.g., register) they can detect or correct. For example, a single-bit parity checker, which computes an XOR of the data bits in the memory unit, can generally only detect single errors. If two errors occur in the same memory unit, then the parity circuit cannot detect the errors. (The term “memory unit” refers to a memory structure such as a register or cache word of any size that stores a unit of memory having an error detection indicia such as a parity value. It could be any size, such as 1, 16, 64 or 256 bits in length, and could use any suitable error checking scheme, such as parity.) Also, in some systems, not more than a single bit in the memory unit may be correctable. Consequently, error accumulation in the same memory unit is problematic. In a data word protected with parity, a second accumulated error can mask detection of the error, potentially causing a “silent” data corruption.

With conventional systems, error checking is typically activated when a specific data word is accessed. Hence, if the parity circuit is not activated between two soft errors (e.g., arising from atmospheric neutrons or alpha particles from packaging material) in a data word, then a tolerable single bit error can turn into a problematic double bit error, which can either go unnoticed (for a parity circuit) or result in a correctable error becoming a non-correctable multi-bit error. Under normal operation in many computing systems, when a processing unit (core) accesses a structure protected with parity, this is generally not problematic because the processing unit typically accesses most (if not all) blocks of a cache within a short time window (e.g., seconds as opposed to months or years, which is typically the time between two soft errors to occur within a single data word under normal operating power conditions). Hence, single bit errors are normally detected or corrected before a second error can arise, accumulate, and cause problems.

It has been observed, however, that the situation is different when structures are powered down to so called “drowsy” (dormant, sleep, etc.) states. Many computing devices have the ability to power down specific structures by lowering the power supplied to the structure. This helps save power, particularly in periods when the structures are not heavily used. Unfortunately, however, the rate of soft errors goes up rapidly for data words located in structures that are in such drowsy states. For example, with some systems, for each 100 mV reduction in supply voltage, a neutron or alpha particle induced soft error rate can go up by 10 to 20%. Thus, when the supply voltage is reduced to its lowest allowed level, the soft error rate can be problematic. Consequently, memory units in drowsy states are vulnerable to soft errors. Accordingly, solutions to this problem are provided herein. In some embodiments, a dormant error checking solution is provided that involves periodically waking up and checking memory units for errors.

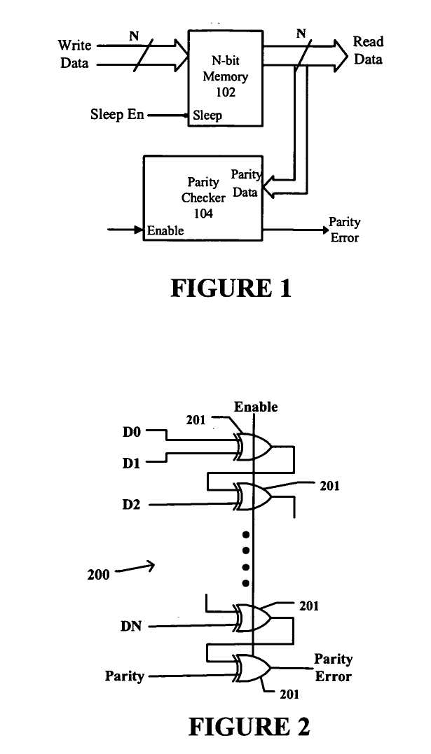

FIG. 1 generally shows an error checking (parity checker) circuit 104 coupled to a register memory unit 102. The depicted N-bit register 102 has read and write ports, with a read port coupled to the parity checker 104 to provide it with data and parity information upon initiation of an error check operation. The error checker 104 is also coupled to circuitry (not shown) to control and/or initiate error checking and memory unit awakening. This control circuit functionality can be implemented with any suitable circuitry on an integrated circuit chip. For example, it could be implemented with an on-board controller, dedicated circuitry, or through software on a higher architectural level.

In the depicted embodiment, the parity checker 104 has an enable input to enable/disable the parity checker circuit. In some embodiments, this allows the parity checker circuit itself to be placed in a drowsy (or sleep) mode when disabled, thereby complementing the power savings obtained from the memory unit.

In operation, the control functionality circuitry periodically wakes up the register 102 and causes the parity checker 104 to check its data word for an error. The parity checker then indicates whether an error was found through a “Parity Error” signal. In some embodiments, if it finds an error, it wakes up the structure containing the memory unit and initiates machine check and/or error correction operations.

Embodiments disclosed herein encompass checking for errors in any suitable memory unit including registers, cache rows/columns and the like, operating in different application environments in an integrated circuit. For example, often a write-through cache is protected with parity. If a parity error is detected on a data portion of the cache, the cache can flush the block and re-fetch it, thereby correcting the error. Likewise, core pipeline register words can be checked during drowsy (e.g., dormant, sleep) modes. Upon detecting such an error, the parity checker could then signal the cache or pipeline to “wake up” and take appropriate recovery actions, such as scrubbing the error inline and writing corrected data back to the corresponding memory structure.

It should be appreciated that while what is depicted is a single error checker block coupled to an associated register structure, in some systems, multiple error checkers that are each coupled to one or more associated memory units could be employed. The multiple error checkers could be coupled to a common controller or to one or more separate controller circuits.

FIG. 2 shows an embodiment of a parity checker circuit 200 suitable for implementing the parity checker 104 of FIG. 1. It comprises N+1 XOR gates 201 cascaded together, as indicated, to check parity for a data word comprising data bits D0 to DN based on the value of the indicated “Parity” signal. If the data word's parity is correct, the output “Parity Error” signal is de-asserted, but if the parity is not correct, the signal is asserted.

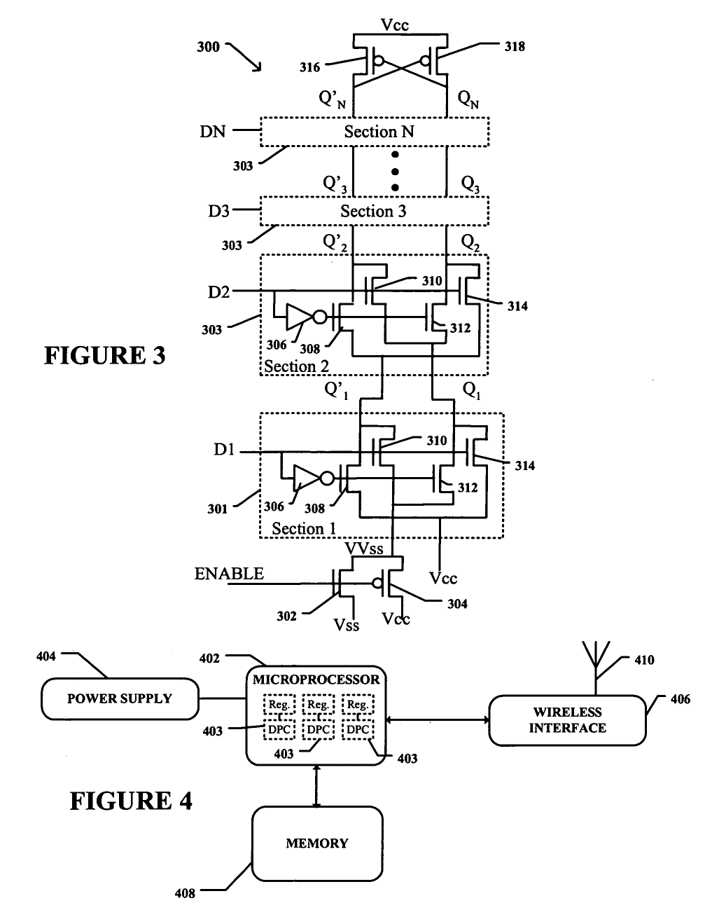

FIG. 3 is a schematic diagram showing a particular circuit 300 to implement a parity checker circuit such as circuit 104. Parity checking circuit 200 generally comprises complementary switch sections 301 (Section 1 to Section N) coupled together, as indicated, between cross-coupled pull-up P-type field-effect-transistors (FETs) 316, 318 and low and high supply references, VVss and Vcc, respectively. The low supply reference, VVss, is a virtual Vss that is enabled through N-type FET 302 when “ENABLE” is High, and disabled (tied to Vcc) through P-type FET 304 when the “ENABLE” signal is Low.

The parity checker circuit 300 determines parity for an N−1 bit word (there are N data inputs, D1 to DN, but one is used for the parity bit). Each section 301 has a separate data input line (D1, D2 . . . DN) and associated complementary output nodes (Qi, Q′ᵢ), with output node Q_{N} serving as the parity output for the overall parity checker. (Apart from the parity output, QN, these nodes are typically not provided as output signals.)

Each section 301 comprises an inverter 306, and N-type transistors 308, 310, 312, and 314. As indicated in Section 1, they are configured to apply a 0/1 across Q₁′/Q₁ when D1 is High, and 1/0 across these lines when it is Low. Sections 2 through N are configured slightly differently to provide at their outputs the complement value of the preceding outputs if their data input is High, and to pass through the preceding output values if the data input is Low. In this way, with one of the data inputs being a parity bit and the others corresponding to bits in a data word with that parity, a parity check operation is implemented with the result provided at QN. This circuit can be efficiently implemented in terms of both layout and power consumption, and it can be placed in a drowsy (power saving) state when the ENABLE signal is de-asserted.

With reference to FIG. 4, one example of a computer system is shown. The depicted system generally comprises a processor 402 that is coupled to a power supply 404, a wireless interface 406, and memory 408. The processor is coupled to the power supply 404 to receive power from it when in operation. The wireless interface 406 is coupled to an antenna 410 to communicatively link the processor through the wireless interface chip 406 to a wireless network (not shown). Microprocessor 402 comprises one or more dormant parity checker circuits 403 with associated register memory units to check their parity when they are in drowsy states.

It should be noted that the depicted system could be implemented in different forms. That is, it could be implemented in a single chip module, a circuit board, or a chassis having multiple circuit boards. Similarly, it could constitute one or more complete computers, or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include, but are not limited to, processors, controllers, chip set components, programmable logic arrays (PLA), memory chips, network chips, and the like.

Moreover, it should be appreciated that although example sizes/models/ values/ranges may have been given, the present invention is not limited to the same. As manufacturing techniques (e.g., photolithography) mature over time, it is expected that devices of smaller size could be manufactured. In addition, well known power/ground connections to IC chips and other components may or may not be shown within the Figures for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
a memory unit to store data; and
an error checking circuit coupled to the memory unit to check its data for an error when it is in a dormant state.

2. The chip of claim 1, in which the memory unit comprises a register in a microprocessor core.

3. The chip of claim 1, in which the error checking circuit comprises a parity checker circuit.

4. The chip of claim 3, in which the parity checker circuit comprises XOR circuits cascaded together to perform a parity function and has a disable capability to save power when the memory unit is in the dormant state.

5. The chip of claim 3, in which the parity checker circuit comprises a plurality of complementary switch sections coupled between cross-coupled pull-up transistors and supply references including a virtual Vss reference.

6. The chip of claim 1, comprising additional error checking circuits coupled to associated memory units, the error checking and additional error checking circuits being coupled to a common controller to initiate error checking when their associated memory units are in dormant states.

7. The chip of claim 6, in which the error checking and additional error checking circuits are to be in dormant states themselves when their associated memory unit circuits are in the dormant states.

8. A chip, comprising:
registers to store data words; and
an error checking circuit for each of the registers to check their data word for an error when it is in a dormant state.

9. The chip of claim 8, in which the at least one register comprises a register in a microprocessor core.

10. The chip of claim 8, in which the error checking circuits comprise parity checking circuits.

11. The chip of claim 10, in which the parity checking circuits each comprise XOR circuits cascaded together to perform a parity function and have a disable capability to save power when their register is in the dormant state.

12. The chip of claim 10, in which the parity checking circuits each comprise a plurality of complementary switch sections coupled between cross-coupled pull-up transistors and supply references including a virtual Vss reference.

13. The chip of claim 12, in which the error checking circuits are to be in dormant states themselves when their associated register is in the dormant state.

14. A system, comprising:
(a) a microprocessor comprising a memory unit to store data, and an error checking circuit coupled to the memory unit to check its data for an error when it is in a dormant state;
(b) an antenna; and
(c) a wireless interface coupled to the microprocessor and to the antenna to communicatively link the microprocessor to a wireless network.

15. The system of claim 14, in which the memory unit comprises a register in a core of the microprocessor.

16. The system of claim 14, in which the error checking circuit comprises a parity checking circuit.

17. The system of claim 16, in which the parity checking circuit comprises XOR circuits cascaded together to perform a parity function and has a disable capability to save power when the memory unit is in the dormant state.

18. The system of claim 3, in which the parity checker circuit comprises a plurality of complementary switch sections coupled between cross-coupled pull-up transistors and supply references including a virtual Vss reference.

19. The system of claim 14, comprising additional error checking circuits coupled to associated memory units, the error checking and additional error checking circuits being coupled to a common controller to initiate error checking when their associated memory units are in dormant states.

20. The system of claim 14 comprising a battery to provide supply power to the microprocessor.
